(19) United States
(12) Patent Application Publication
(10) Pub. No.: US 2024/0149391 A1
(43) Pub. Date: May 9, 2024

(54) PROCESSING APPARATUS

(71) Applicant: TOKYO SEIMITSU CO., LTD., Hachioji-shi, Tokyo (JP)

(72) Inventor: Tadashi MURASATO, Hachioji- shi, Tokyo (JP)

(21) Appl. No.: 18/281,941

(22) PCT Filed: Dec. 7, 2021
(86) PCT No.: PCT/JP2021/044820

§ 371 Date: Sep. 13, 2023

(30) Foreign Application Priority Data
Mar. 23, 2021 (JP) 2021-048841

(51) Int. Cl. B24B 37/30

(52) U.S. Cl. CPC B24B 37/30

(57) ABSTRACT

A processing apparatus that flattens a workpiece to a desired thickness. A processing apparatus 1 that flattens a workpiece W having a non-circular shape with a grinding stone 21, the processing apparatus 1 including a suction member 33 capable of suction-holding the workpiece W, and an attachment 37 that is provided on an outer periphery side of the suction member 33. The attachment 37 is composed of a material harder to grind than the suction member 33, and can contact the grinding stone 21 during self-grinding for grinding the suction member 33.

### TECHNICAL FIELD

The present invention relates to a processing apparatus that flattens a workpiece.

### BACKGROUND ART

In a semiconductor manufacturing field, there has been known a processing apparatus that flattens a semiconductor workpiece such as a silicon wafer (hereinafter referred to as a “workpiece”) to be thin and flat.

Patent Literature 1 discloses a grinding device that grinds a rectangular workpiece held in a chuck table to a predetermined thickness by bringing a grinding stone that rotates into contact with an upper surface of the rectangular workpiece.

### CITATION LIST

### Patent Literature

Patent Literature 1: Japanese Patent Application No. 5230982

### SUMMARY OF INVENTION

### Technical Problem

However, when a workpiece is flattened, a thickness variation may occur in the workpiece after the processing due to an influence of the accuracy of a fixed surface of the workpiece and the attachment accuracy of a processing tool such as a grinding stone. To solve the thickness variation, the fixed surface of the workpiece and the processing tool need to have conventionally been reassembled or adjusted.

Further, when a workpiece having a shape excluding a circular shape and a workpiece provided with an orientation flat (hereinafter generically referred to as a “non-circular workpiece”) are subjected to in-feed processing, a contact area between the grinding stone and the workpiece for each predetermined rotation of a chuck table is not constant, but a grinding amount of the workpiece tends to decrease in a region where the contact area is relatively wide and tends to increase in a region where the contact area is relatively narrow. That is, there has been a problem that the workpiece cannot be finished to a desired thickness because the workpiece varies in thickness depending on whether the contact area between the grinding stone and the workpiece during the processing is large or small.

Therefore, there occurs a technical problem to be solved to flatten a workpiece to a desired thickness, and the present invention has its object to solve this problem.

### Solution to Problem

To attain the above-described object, a processing apparatus according to the present invention is a processing apparatus that flattens a workpiece with a grinding stone, the processing apparatus including an suction member capable of suction-holding the workpiece, and an attachment that is provided on an outer periphery side of the suction member, is composed of a material harder to grind than the suction member, and can contact the grinding stone during self-grinding for grinding the suction member.

According to this configuration, to compensate for a thickness variation in the workpiece after the flattening, a thickness of the suction member after the self-grinding in a region where the grinding stone contacts the suction member and the attachment is larger than a thickness of the suction member after the self-grinding in a region where the grinding stone contacts the suction member, thereby making it possible to reduce the thickness variation in the workpiece after the flattening.

### Advantageous Effect of Invention

The present invention makes it possible to reduce a thickness variation in a workpiece after flattening due to the accuracy of a fixed surface of the workpiece, the attachment accuracy of a processing tool, or a shape of the workpiece.

### BRIEF DESCRIPTION OF DRAWINGS

FIG. 1 is a schematic view illustrating a processing apparatus according to an embodiment of the present invention.

FIG. 2 is a perspective view illustrating a chuck table.

FIG. 3 is a diagram illustrating the chuck table illustrated in FIG. 2, where FIG. 2(a) is a plan view and FIG. 2(b) is a cross-sectional view taken along a line A-A in FIG. 2(a).

FIG. 4 is a schematic view illustrating how self-grinding is performed.

FIG. 5 is a plan view illustrating comparison between respective contact areas between a workpiece and a grinding stone in two portions in the workpiece.

FIG. 6 is a schematic view illustrating respective thicknesses of the workpiece after flattening in the two portions illustrated in FIG. 5.

FIG. 7 is a plane view illustrating a positional relationship of an attachment with a suction member.

FIG. 8(a) is a schematic view illustrating respective thicknesses after self-grinding in two portions in the suction member, and FIG. 8 (b) is a schematic view illustrating respective thicknesses after flattening in two portions in the workpiece.

FIG. 9 is a perspective view illustrating a chuck table to be applied to a processing apparatus according to a modification to the present invention.

FIG. 10 is a diagram illustrating the chuck table illustrated in FIG. 9, where FIG. 10(a) is a plan view and FIG. 10(b) is a cross-sectional view taken along a line B-B in FIG. 10(a).

### DESCRIPTION OF EMBODIMENT

An embodiment of the present invention will be described with reference to the drawings. Hereinafter, when reference is made to the number of components or a numerical value, amount, range, or the like of each of the components, the number or the like is not limited to a particular number but may be the particular number or more or the particular number or less unless otherwise stated or except when expressly limited to the particular number in principle.

When reference to a shape of each of components and a positional relationship among the components, a substantially approximate or similar shape or the like is included unless otherwise stated or except when considered to be expressly excluded in principle.

In the drawings, there is a case where characteristic portions are exaggerated by being enlarged, for example, in order to facilitate the understanding of features, and a dimension ratio or the like of each of the components is not necessarily the same as an actual one. In a cross-sectional view, hatching of some of the components may be omitted in order to facilitate the understanding of a cross-sectional structure of the components.

In the present embodiment, terms representing directions such as up-down and left-right directions are not absolute, but are appropriate if each of the components is in an orientation depicted in the drawings. However, if the orientation has changed, the terms should be construed by being changed depending on the change in the orientation.

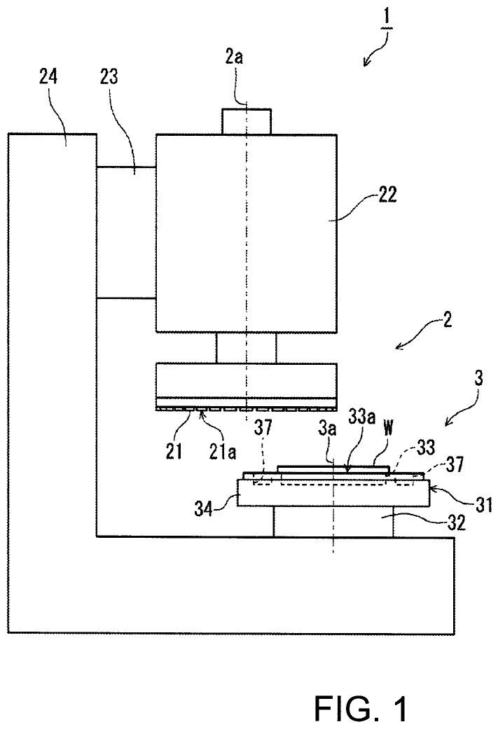

A processing apparatus 1 grinds a workpiece W. As illustrated in FIG. 1, the processing apparatus 1 includes a processing section 2 and a holding section 3.

The processing section 2 includes a grinding stone 21, a grinding stone spindle 22, and an in-feed mechanism 23.

The grinding stone 21 is a cup-shaped grinding stone, for example, and is attached to a lower end of the grinding stone spindle 22.

The grinding stone spindle 22 is configured to be rotatable around a rotation axis 2a and such that the grinding stone 21 and the grinding stone spindle 22 are integrally rotatable.

The in-feed mechanism 23 raises and lowers the grinding stone spindle 22 in a vertical direction. The in-feed mechanism 23 has a known configuration, and is constituted by a plurality of linear guides that guide a movement direction of the grinding stone spindle 22 and a ball screw slider mechanism that raises and lowers the grinding stone spindle 22. The in-feed mechanism 23 is interposed between the grinding stone spindle 22 and a column 24.

The holding section 3 includes a chuck table 31 and a chuck spindle 32.

The chuck table 31 includes an suction member 33 composed of a porous material such as alumina on its upper surface and a dense body 34 with the suction member 33 embedded at its substantial center.

The chuck table 31 includes a duct not illustrated extending to its surface through its inner portion. The duct is connected to a vacuum source, a compressed air source, or a water supply source via a rotary joint not illustrated. When the vacuum source is started, a negative pressure occurs between the workpiece W placed on the suction member 33 and an upper surface (suction surface 33a) of the suction member 33, whereby the workpiece W is suction-held on the suction surface 33a. When the compressed air source or the water supply source is started, suction between the workpiece W and the suction member 33 is released.

The suction member 33 is formed in a shape corresponding to the workpiece W having a rectangular shape as viewed from the top.

The chuck spindle 32 is configured to drive the chuck table 31 to rotate around a rotation axis 3a. A driving source of the chuck spindle 32 may be a servo motor, for example.

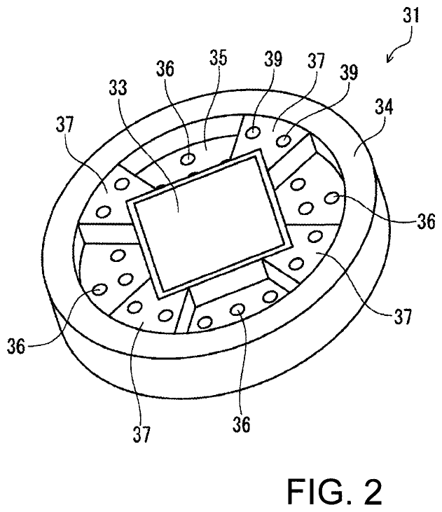

As illustrated in FIG. 2, an annular recess 35 is formed to surround the suction member 33 in the chuck table 31. A plurality of bolt holes 36 are formed in a bottom portion of the annular recess 35. The annular recess 35 need not be formed on the entire periphery of the suction member 33, but may be locally formed in a range to which an attachment 37, described below, can be attached.

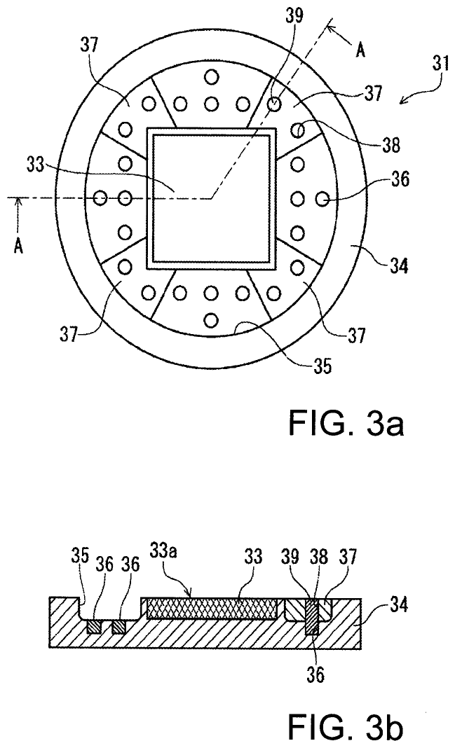

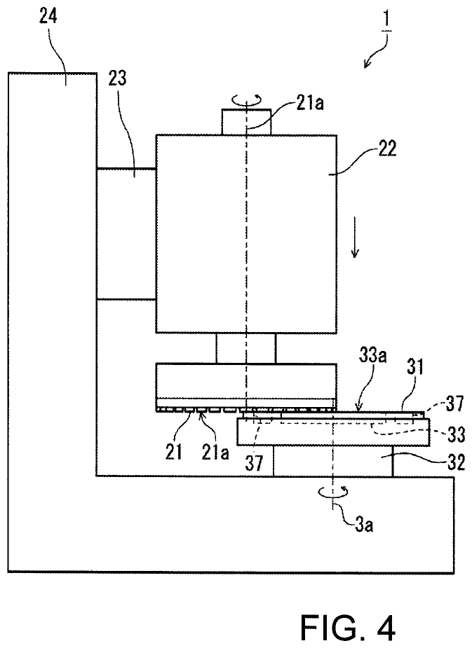

The attachment 37 is attached to the annular recess 35. Specifically, as illustrated in FIG. 3(a), the attachment 37 is provided to close a space between four corners of the suction member 33 and an outer edge of the chuck table 31 in a radial direction of the chuck table 31 as viewed from the top. The attachment 37 may be a material hard to grind having a higher hardness than that of the suction member 33, and is composed of a similar material to that composing the dense body 34, for example. As illustrated in FIG. 3(b), the suction surface 33a and an upper surface (a contact surface 37a) of the attachment 37 are substantially flush with each other with the attachment 37 attached to the chuck table 31.

The attachment 37 has a bolt hole 38 formed by virtually penetrating therethrough. The attachment 37 is fastened to be detachably attached to the chuck table 31 via a bolt 39. A corner of the contact surface 37a is preferably chamfered to suppress chipping with the grinding stone 21.

An operation of the processing apparatus 1 is controlled by a control unit not illustrated. The control unit controls each of components constituting the processing apparatus 1. The control unit includes a CPU and a memory, for example. A function of the control unit may be implemented by control using software or may be implemented by operating using hardware.

Then, self-grinding of the processing apparatus 1 will be described with reference to the drawings.

The self-grinding refers to a process for bringing the grinding stone 21 into contact with the chuck table 31 by the in-feed mechanism 23 to grind the suction surface 33a of the suction member 33 with the grinding stone 21. The self-grinding is appropriately performed to maintain the suction surface 33a to a desired shape, and is generally performed prior to flattening of the workpiece W when the chuck table 31 is replaced.

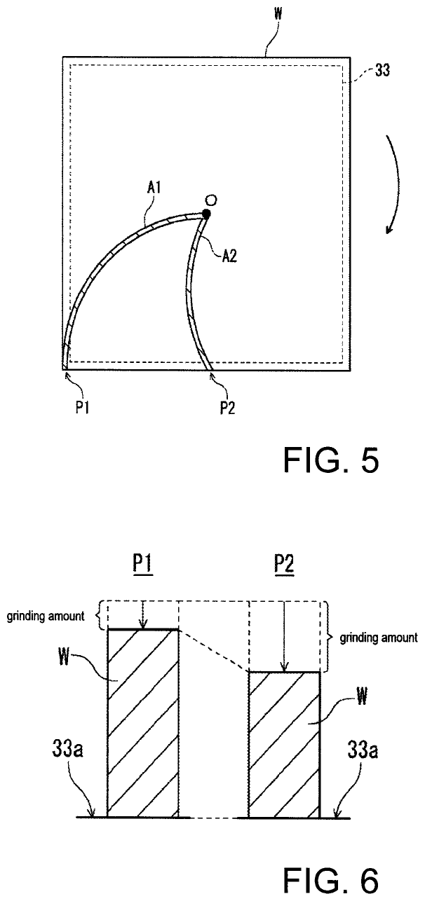

When the processing apparatus 1 brings a processing surface of the grinding stone 21 into parallel contact with a surface to be processed of the workpiece W having a non-circular shape, a processing amount (grinding amount) of the workpiece W may be unstable within a plane. The reason for this will be described below with reference to FIG. 5. Although the workpiece W having a square shape as viewed from the top is described below as an example, the shape of the workpiece W is not limited to this.

Comparison between a contact region A1 between the workpiece W and the grinding stone 21 in a case where the processing surface of the grinding stone 21 contacts the workpiece W to pass through a corner of the workpiece W and a rotation center O of the chuck table 31 and a contact region A2 between the workpiece W and the grinding stone 21 in a case where the processing surface of the grinding stone 21 contacts the workpiece W to pass through the center of a side of the workpiece W and the rotation center O shows that the contact region A1 is approximately two times wider than the contact region A2, as illustrated in FIG. 5.

When the grinding stone 21 is brought into uniform contact with the workpiece W over its entire surface, a grinding amount of the workpiece W decreases so that the workpiece W after processing thickens as a contact area between the workpiece W and the grinding stone 21 increases. That is, when respective thicknesses of the workpiece W after grinding in the contact regions A1 and A2 are compared with each other, the workpiece W in the contact region A2 is formed to be thicker than the workpiece W in the contact region A1, as illustrated in FIG. 6. For example, the workpiece W that is 280 mm square is ground in an end portion P2 of the contact region A2 to be thinner by approximately 4 μm than that in an end portion P1 of the contact region A1.

In the processing apparatus 1, a grinding amount in the self-grinding is locally increased or decreased within the suction member 33 to compensate for a change in thickness of the workpiece W depending on a change in contact area between the workpiece W and the grinding stone 21 that contact each other during flattening.

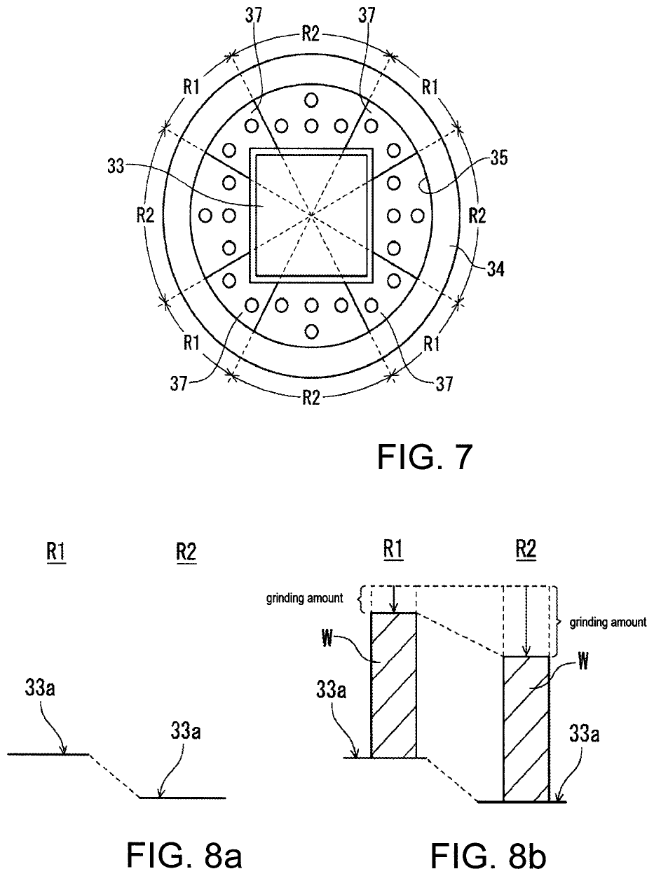

Specifically, as illustrated in FIG. 7, first processing regions R1 where the grinding amount of the workpiece W is relatively small and second processing regions R2 where the grinding amount of the workpiece W is relatively large during flattening are assumed, and the attachment 37 is arranged on the outer periphery of the suction member 33 in each of the first processing regions R1.

In the present embodiment, each of the first processing regions R1 is set to have a fan shape having a central angle of +15 degrees around a diagonal line of the suction member 33, and each of the second processing regions R2 is set to have a substantially fan shape having a central angle of 60 degrees between the adjacent first processing regions R1. The size of each of the processing regions R1 and R2 may be appropriately changed depending on a processing condition of the workpiece W, for example.

The attachment 37 is composed of a material harder to grind than the suction member 33. Accordingly, a grinding amount of the suction member 33 in the first processing region R1 is smaller than a grinding amount of the suction member 33 in the second processing region R2 at the time of the self-grinding, whereby the suction member 33 in the first processing region R1 is ground to be locally thick, as illustrated in FIG. 8(a).

When the workpiece W is flattened, a grinding amount of the workpiece W in the first processing region R1 is smaller than a grinding amount of the workpiece W in the second processing region R2 at the time of flattening, whereby the workpiece W in the first processing region R1 is processed to be thicker than the workpiece W in the second processing region R2, as illustrated in FIG. 8 (b).

Thus, a difference between the respective grinding amounts in the first processing region R1 and the second processing region R2 at the time of the flattening is compensated for by a difference between respective thicknesses of the first processing region R1 and the second processing region R2 in the suction member 33, thereby reducing a thickness variation in the workpiece W after the flattening.

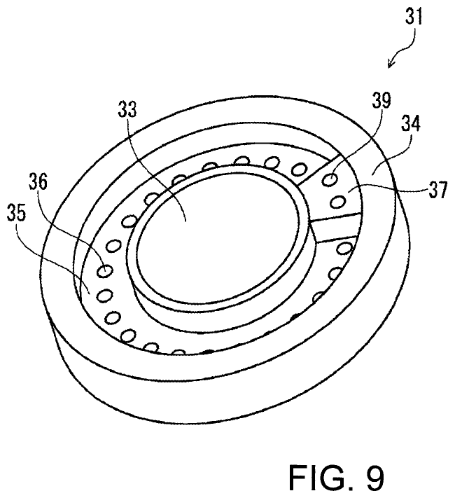

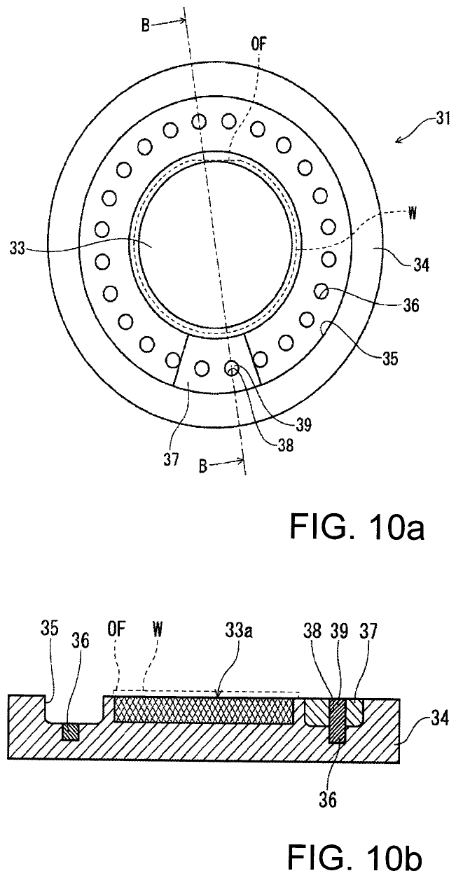

Respective shapes of the suction member 33 and the attachment 37 are not limited to the above-described shapes. When the chuck table 31 suction-holds a workpiece W having an orientation flat OF formed therein, for example, the suction member 33 may be formed in a circular shape as viewed from the top and the attachment 37 may be formed in an annular fan shape as viewed from the top, as illustrated in FIGS. 9, 10(a), and 10(b).

Thus, the processing apparatus 1 according to the present embodiment is the processing apparatus 1 that flattens the workpiece W with the grinding stone 21, the processing apparatus being configured to include the suction member 33 capable of suction-holding the workpiece W and the attachment 37 that is provided on the outer periphery side of the suction member 33, is composed of a material harder to grind than the suction member 33, and can contact the grinding stone 21 during self-grinding for grinding the suction member 33.

According to this configuration, when the grinding stone 21 flattens the workpiece W, a thickness of the suction member 33 after the self-grinding in the first processing region R1 where the grinding stone 21 contacts the suction member 33 and the attachment 37 is larger than a thickness of the suction member 33 after the self-grinding in the second processing region R2 where the grinding stone 21 contacts the suction member 33 to compensate for a thickness variation in the workpiece W after the processing due to a contact area between the grinding stone 21 and the workpiece W changing depending on a rotational angle of the chuck table 31, thereby making it possible to reduce the thickness variation in the workpiece W after the flattening.

The processing apparatus 1 according to the present embodiment is configured such that the attachment 37 is provided to be detachably attached to the chuck table 31 that accommodates the suction member 33.

This configuration makes it possible to change a position of the attachment 37 relative to the suction member 33, thereby making it possible to change a shape of the suction member 33 after the self-grinding depending on a shape of the workpiece W and a processing condition.

The processing apparatus 1 according to the present embodiment is configured such that the workpiece W is formed in a non-circular shape.

This configuration makes it possible to reduce the thickness variation in the workpiece W after the flattening due to the shape of the workpiece W.

It should be understood that various modifications can be made in addition to the foregoing without departing from the spirit of the prevent invention and the present invention covers the modifications. The above-described embodiment and modifications may be combined with each other.

### REFERENCE SIGNS LIST

1: processing apparatus
2: processing section
21: grinding stone
22: grinding stone spindle
23: in-feed mechanism
24: column
3: holding section
31: chuck table
32: chuck spindle
33: suction member
33a: suction surface
34: dense body
35: annular recess
36: bolt hole (of dense body)
37: attachment
37a: contact surface
38: bolt hole (of attachment)
39: bolt
R1: first processing region
R2: second processing region
W: workpiece

1. A processing apparatus that flattens a workpiece with a grinding stone, the processing apparatus comprising:
a suction member capable of suction-holding the workpiece; and
an attachment that is provided on an outer periphery side of the suction member, to be detachably attached to a chuck table that accommodates the suction member, is composed of a material harder to grind than the suction member, and can contact the grinding stone during self-grinding for grinding the suction member.

2. (canceled)

3. The processing apparatus according to claim 1, wherein the workpiece is formed in a non-circular shape.
